(19) United States
(12) Patent Application Publication
(10) Pub. No.: US 2013/0302984 A1
(43) Pub. Date: Nov. 14, 2013

(54) POLISHING COMPOSITION, POLISHING METHOD USING SAME, AND SUBSTRATE PRODUCTION METHOD

(71) Applicants: Kohsuke Tsuchiya, Kiyosu-shi (JP); Megumi Kubo, Kiyosu-shi (JP); Shuhei Takahashi, Kiyosu-shi (JP)

(72) Inventors: Kohsuke Tsuchiya, Kiyosu-shi (JP); Megumi Kubo, Kiyosu-shi (JP); Shuhei Takahashi, Kiyosu-shi (JP)

(73) Assignee: FUJIMI INCORPORATED

(21) Appl. No.: 13/980,138

(22) PCT Filed: Jan. 18, 2012
(86) PCT No.: PCT/JP2012/050935

§ 371 Date: Jul. 17, 2013

(30) Foreign Application Priority Data
Jan. 26, 2011 (JP) 2011-014055

(51) Int. Cl. H01L 21/306; C09G 1/04

(52) U.S. Cl. CPC H01L 21/30625; C09G 1/04
USPC 438/692; 252/79.1

(57) ABSTRACT

Provided is a polishing composition characterized by: including at least one of either organic acid or organic salt and including a composition (A) including hydroxyethyl cellulose, ammonia, abrasive grains, and water. The electrical conductivity of the polishing composition is 1.2 to 8 times the electrical conductivity of the composition (A). The polishing composition is mainly used in substrate surface polishing applications.

### TECHNICAL FIELD

The present invention relates to a polishing composition for use in polishing a substrate, a method for polishing a substrate by using the polishing composition, and a method for producing a substrate.

### BACKGROUND ART

In semiconductor devices such as ULSIs (Ultra Large Scale Integrations) used in computers, movement to smaller design rules in order to realize higher integration and higher operation speed has been accelerated year by year. With this tendency, there are an increased number of cases where small defects on the surface of a substrate used in a semiconductor device have an adverse effect on the performance of the semiconductor device. Accordingly, overcoming nano-scale surface defects, which have never been regarded as a problem, has become important.

Surface defects of a substrate are detected as light point defects (LPDs). LPDs are classified into those ascribed to crystal originated particles (COP) and those ascribed to foreign matter adhered to a substrate surface.

Since COPs are structural defects of crystals produced in pulling a silicon ingot, it is difficult to remove COPs by polishing. In contrast, LPDs ascribed to foreign matter adhered to a substrate surface include LPDs ascribed to polishing materials, additives such as a water soluble polymer compound, pad debris, substrate swarf, dust in air and other foreign matters, which have not been completely removed in a cleaning step.

The presence of LPDs on a substrate surface causes deterioration of device characteristics such as a pattern defect and withstand voltage failure in a step for forming a semiconductor device, which reduces the yield. For this reason, it is necessary to reduce LPDs on a substrate surface. Furthermore, to reduce nano-scale LPDs, which have never been regarded as a problem, it is necessary to detect LPDs at a higher sensitivity. However, in the case where a substrate has a very small degree of surface roughness, light emitted from a probe of a surface-defect detection apparatus is reflected diffusely by the substrate surface. This phenomenon may generate noise during detection of LPDs. The fogging of the substrate caused by the diffuse reflection is referred to as haze. To detect LPDs at a higher sensitivity, it is necessary to improve the haze level of a substrate surface.

Patent Document 1 discloses a polishing composition that reduces LPDs ascribed to foreign matter adhered to a substrate surface. The polishing composition disclosed in Patent Document 1 employs a water soluble polymer in order to prevent foreign matter from being adhered to a substrate surface by removal of water from and drying of the substrate surface after it is polished.

However, the hydrophilicity of a substrate surface imparted by the polishing composition disclosed in Patent Document 1 is not sufficient to suppress adhesion of foreign matter to the substrate surface. Accordingly, to reduce nano-scale LPDs, which have never been regarded as a problem, it is required to develop a technique for further improving hydrophilicity of a substrate surface.

### PRIOR ART DOCUMENT

Patent Document 1: Japanese Laid-Open Patent Publication No. 11-116942

### SUMMARY OF THE INVENTION

### Problems that the Invention is to Solve

The present invention is made to overcome problems as mentioned above. An object of the present invention is to provide a polishing composition that is used in a step for polishing a substrate, imparts high hydrophilicity to a substrate surface after polished in order to reduce LPDs of the substrate surface after polished, and to provide a method for polishing using the polishing composition and a method for producing a substrate.

### Means for Solving the Problems

The present inventors conducted intensive studies with a view to solving the aforementioned problems. As a result, they found that the hydrophilicity of the substrate surface after polished was improved without deteriorating the haze level by using a polishing composition containing a composition (A), which contained hydroxyethyl cellulose, abrasive grains, ammonia and water, and at least one selected from an organic acid and an organic salt, and of which the electrical conductivity was controlled to fall within the most suitable range. The inventors thus reached the present invention.

That is, the polishing composition according to the present invention includes a composition (A) and at least one selected from an organic acid and an organic salt. The composition (A) contains hydroxyethyl cellulose, ammonia, abrasive grains, and water. The electrical conductivity of the polishing composition is 1.2 to 8 times the electrical conductivity of the composition (A).

A polishing method of the present invention is a method for polishing a substrate surface by using the above described polishing composition. A method for manufacturing a substrate of the present invention includes a step for polishing a substrate surface by using the above polishing method.

### Effects of the Invention

Satisfactory hydrophilicity can be imparted to a substrate surface after polished by polishing the substrate by using the polishing composition of the present invention. As a result, it is possible to reduce nano-scale LPDs.

### MODES FOR CARRYING OUT THE INVENTION

Embodiments of the present invention will now be described below.

[1] The Polishing Composition of the Present Invention

The polishing composition of the present invention is characterized by containing a composition (A), which contains hydroxyethyl cellulose, abrasive grains, ammonia and water, and one selected from an organic acid and an organic salt, in which the electrical conductivity of the polishing composition is 1.2 to 8 times the electrical conductivity of the composition (A).

A polishing composition containing hydroxyethyl cellulose and an organic acid or an organic salt imparts an improved hydrophilicity to the substrate surface after polished. The present inventors empirically found that the improved hydrophilicity varied depending upon the increase rate of the electrical conductivity of the polishing composition due to an organic acid and an organic salt.

Electrical conductivity is a value expressing the ability of a substance to allow electricity to go through it and expressed by an SI unit of S/cm. Generally, the higher the concentration of charged ions in a liquid, the easier the electricity goes through the liquid. Therefore, the electrical conductivity of such a liquid increases. In other words, an increase in electrical conductivity of the polishing composition of the present invention means an increase in concentration of ions in the composition. An increase rate of electrical conductivity due to an organic acid and an organic salt of the polishing composition of the present invention is calculated by dividing the electrical conductivity value of the polishing composition of the present invention by the electrical conductivity value of the composition (A). The electrical conductivity of the composition (A) and the polishing composition can be measured, for example, by a conductivity meter DS-14 manufactured by Horiba, Ltd. at a liquid temperature of 25° C.; however the measurement of electrical conductivity is not limited to this manner.

To improve the hydrophilicity of the substrate surface after polished, it is necessary that the electrical conductivity of the polishing composition be no less than 1.2 times the electrical conductivity of the composition (A) and preferably no less than 1.4 times the electrical conductivity of the composition (A). If the electrical conductivity of the polishing composition is significantly smaller than the electrical conductivity of the composition (A), hydrophilicity of the substrate surface after polished becomes insufficient.

In contrast, according to the studies of the present inventors, it was found that if the electrical conductivity of the polishing composition, in other words, the ionic concentration of the polishing composition, was excessively large, the haze level of the substrate surface after polished was adversely affected. Therefore, to prevent deterioration of the haze level of the substrate surface after polishing, it is necessary that the electrical conductivity of the polishing composition be no greater than 8 times the electrical conductivity of the composition (A) and preferably no greater than 5 times the electrical conductivity of the composition (A). If the electrical conductivity of the polishing composition is excessively larger than the electrical conductivity of the composition (A), the haze level of the substrate surface after polished deteriorates and thus not preferable. In view of this, if an organic acid or an organic salt is a monocarboxylic acid or a salt thereof, the electrical conductivity of the polishing composition is more preferably no greater than 3.5 times the electrical conductivity of the composition (A). Furthermore, if the concentration of the organic acid or the organic salt is significantly high, the abrasive grains in the polishing composition easily form a gel. Accordingly, in view of the stability of the polishing composition, the electrical conductivity of the polishing composition is more preferably no greater than 3 times the electrical conductivity of the composition (A).

The organic acid and organic salt contained in the polishing composition of the present invention serve to control the electrical conductivity i.e., the ionic concentration of the polishing composition. The organic acid is not limited by type, structure and ionic valence. Furthermore, a salt of any organic acid may be used as the organic salt, and the organic salt is not limited by type, structure and ionic valence of the organic acid, and the type of base. Examples of the organic acid and the organic acid forming the organic salt to be employed in the polishing composition of the present invention include: aliphatic acids such as formic acid, acetic acid and propionic acid; aromatic carboxylic acids such as benzoic acid and phthalic acid; citric acid; oxalic acid; tartaric acid; malic acid; maleic acid; fumaric acid; succinic acid; organic sulfonic acids; and organic phosphoric acids, but are not limited to these. Furthermore, examples of the base forming an organic salt include ammonium ion and various types of metal ions, but are not limited to these. To prevent pollution of a substrate with metal, the base forming an organic salt is preferably an ammonium ion. The organic acids and organic salts may be used alone or in combination with two or more types.

The hydroxyethyl cellulose contained in the polishing composition of the present invention serves to impart hydrophilicity to the substrate surface after polished. Furthermore, the present inventors empirically found that improvement in hydrophilicity of the substrate surface after polished brought by the polishing composition of the present invention specifically occurred particularly by use of hydroxyethyl cellulose among water soluble polymers.

The polyethylene oxide equivalent weight average molecular weight of hydroxyethyl cellulose is preferably 10,000 or more and further preferably 50,000 or more in order to impart sufficient hydrophilicity to the substrate surface after polished. Furthermore, the polyethylene oxide equivalent weight average molecular weight of hydroxyethyl cellulose is preferably 2,000,000 or less and further preferably 500,000 or less in order to improve the dispersion stability of the polishing composition.

The content of hydroxyethyl cellulose in the polishing composition is preferably 0.0001% by mass or more and further preferably 0.001% by mass or more in order to impart sufficient hydrophilicity to the substrate surface after polished. Furthermore, the content of hydroxyethyl cellulose in the polishing composition is preferably 0.5% by mass or less and further preferably 0.1% by mass or less in order to improve the dispersion stability of the polishing composition.

The abrasive grains contained in the polishing composition of the present invention serves to physically polish a substrate surface.

The content of the abrasive grains in the polishing composition is preferably 0.01% by mass or more. The higher the content of the abrasive grains, the higher the polishing rate of a substrate by the polishing composition becomes. Furthermore, the content of the abrasive grains in the polishing composition is preferably 5% by mass or less, more preferably 1% by mass or less and further preferably 0.5% by mass or less. The lower the content of the abrasive grains, the higher the dispersion stability of the polishing composition becomes. In addition, LPD that is ascribed to adhesion of abrasive grains to the substrate surface after polished as a residue decreases.

Examples of abrasive grains to be used in the polishing composition of the present invention include a silicon carbide, a silicon dioxide, alumina, ceria, zirconia and diamond but are not limited to these. Of them, use of silicon dioxide is preferable since the haze level of the substrate surface after polished decreases. Examples of the silicon dioxide include colloidal silica, fumed silica and sol-gel processed silica. The abrasive grains may be used alone or in combination with two or more types.

When the polishing composition is used for polishing a semiconductor substrate, particularly a silicon wafer, the abrasive grains are formed of preferably a silicon dioxide, more preferably colloidal silica or fumed silica, and further preferably colloidal silica. In the case of using colloidal silica or fumed silica, in particular, colloidal silica, the number of scratches produced in the substrate surface in the polishing step decreases.

When the polishing composition is used for polishing a semiconductor substrate, particularly a silicon wafer, the particle diameter of the abrasive grains contained in the polishing composition is preferably 5 nm or more and further preferably 10 nm or more. Furthermore, the particle diameter of the abrasive grains contained in the polishing composition is preferably 100 nm or less and further preferably 40 nm or less. The particle diameter described herein is an average primary particle diameter calculated from a specific surface area that is measured by the specific surface area determination method of a powder by gas adsorption (BET method).

The abrasive grains of the polishing composition preferably have a particle size distribution giving a value (D90/D10) between 1 and 4, which is obtained by dividing 90% cumulative average diameter (D90) on a volume basis by 10% cumulative average diameter (D10) on a volume basis. The 10% cumulative average diameter (D10) on a volume basis refers to the average particle diameter at a point where the cumulative value reaches 10% from the smallest diameter in the particle size distribution shown on a volume basis. Furthermore, the 90% cumulative average diameter (D90) on a volume basis refers to the average particle diameter at a point where the cumulative value reaches 90% from the smallest diameter in the particle size distribution on a volume basis. The particle size distribution on a volume basis can be measured by use of, for example, a particle size distribution measuring apparatus in accordance with a dynamic light scattering method; however, the measuring method is not limited to this manner.

Ammonia contained in the polishing composition of the present invention, which has a chemical etching action to a substrate surface, serves to chemically polish a substrate surface and also serves to improve the dispersion stability of the polishing composition.

The content of ammonia in the polishing composition is preferably 0.0001% by mass or more and further preferably 0.001% by mass or more. As the ammonia content increases, the chemical etching action to a substrate surface is sufficiently obtained, with the result that the polishing rate to the substrate by the polishing composition is increased. In addition, the dispersion stability of the polishing composition is improved. Furthermore, the content of ammonia in the polishing composition is preferably 0.5% by mass or less and further preferably 0.25% by mass or less. As the content of ammonia decreases, excessive chemical etching action is avoided, with the result that the haze level of the substrate surface is improved after polishing.

Water contained in the polishing composition of the present invention serves to dissolve or disperse other components in the polishing composition. It is preferable that water does not contain impurities inhibiting actions of other components as much as possible. To be more specific, e.g., ion exchanged water, which is obtained by removing impurity ions by use of ion exchange resin and thereafter removing foreign matter through a filter, pure water, ultrapure water or distilled water, is preferable.

The pH of the polishing composition of the present invention is preferably 8 or more and further preferably 9 or more. Furthermore, the pH of the polishing composition is preferably 12 or less and further preferably 11 or less. If the pH of the polishing composition falls within the above range, a polishing rate particularly preferable from a practical viewpoint is easily obtained.

The polishing composition of the present invention may further contain a surfactant in addition to the aforementioned components. The surfactant suppresses roughness of a substrate surface ascribed to chemical etching with ammonia and serves to improve a haze level.

The surfactant may be ionic or nonionic. When a nonionic surfactant is used as a polishing composition, foaming of the polishing composition is more suppressed compared to the case where a cationic surfactant or an anion surfactant is used. Thus, it becomes easier to produce or use the polishing composition. Furthermore, a nonionic surfactant does not change the pH of the polishing composition. Thus it becomes easier to control pH at the time of producing or using the polishing composition. Moreover, the nonionic surfactant has excellent biodegradability and toxicity thereof to a living body is low. Thus it is possible to reduce effect on the environment and risk in handling.

Usable surfactants are not limited by its structure. Examples of the usable surfactants include: oxyalkylene homopolymers such as polyethylene glycol and polypropylene glycol; various types of oxyalkylene copolymers such as polyoxyethylene polyoxypropylene diblock copolymers, triblock copolymers, random copolymers, and alternate copolymers; and polyoxyalkylene adducts such as polyoxyethylenealkyl ether, polyoxyethylenealkylphenyl ether, polyoxyethylenealkyl amine, polyoxyethylene aliphatic acid ester, polyoxyethylene glycer ether aliphatic acid ester, and polyoxyethyelenesorbitan aliphatic acid ester. Specific examples of the usable surfactants include polyoxyethylene polyoxypropylene copolymers, polyoxyethylene glycol, polyoxyethylene propyl ether, polyoxyethylene butyl ether, polyoxyethylene pentyl ether, polyoxyethylene hexyl ether, polyoxyethylene octyl ether, polyoxyethylene-2-ethyl hexyl ether, polyoxyethylene nonyl ether, polyoxyethylene decyl ether, polyoxyethylene isodecyl ether, polyoxyethylene tridecyl ether, polyoxyethylene lauryl ether, polyoxyethylene cetyl ether, polyoxyethylene stearyl ether, polyoxyethylene isostearyl ether, polyoxyethylene oleyl ether, polyoxyethylene phenyl ether, polyoxyethylene octyl phenyl ether, polyoxyethylene nonyl phenyl ether, polyoxyethylene dodecyl phenyl ether, polyoxyethylene styrenated phenyl ether, polyoxyethylene lauryl amine, polyoxyethylene stearyl amine, polyoxyethylene oleyl amine, polyoxyethylene stearyl amide, polyoxyethylene oleyl amide, polyoxyethylene monolauric acid ester, polyoxyethylene monostearic acid ester, polyoxyethylene distearic acid ester, polyoxyethylene monooleic acid ester, polyoxyethylene dioleic acid ester, monlauric acid polyoxyethylenesorbitan, monopalmitic acid polyoxyethylenesorbitan, monostearic acid polyoxyethylenesorbitan, monooletic acid polyoxyethylenesorbitan, trioletic acid polyoxyethylenesorbitan, tetraoletic acid polyoxyethylenesorbit, polyoxyethylene castor oil, and polyoxyethylene hydrogenated castor oil, but are not limited to these. The surfactants may be used alone or in combination with two or more types.

In the present invention, the weight average molecular weight of the surfactant is preferably 200 or more and further preferably 300 or more. Furthermore, the weight average molecular weight of the surfactant is preferably 15,000 or less and further preferably 10,000 or less. If the weight average molecular weight of the surfactant falls within the above range, the roughness of a substrate surface is sufficiently suppressed.

The content of the surfactant in the polishing composition is preferably 0.00001% by mass or more and further preferably 0.00005% by mass or more. Furthermore, the content of the surfactant is preferably 0.1% by mass or less and further preferably 0.05% by mass or less. If the content of the surfactant falls within the above range, the roughness of a substrate surface is sufficiently suppressed.

In the present invention, examples of the substrate include a semiconductor substrate and a magnetic substrate but are not limited to these. The polishing composition is suitable for polishing, e.g., a silicon substrate, an SiO₂ substrate, an SOI substrate, a plastic substrate, a glass substrate and a quart substrate, and particularly suitable for polishing a silicon wafer, which is required to have a highly smooth and clean substrate surface.

The reason why the polishing composition of the present invention imparts significantly satisfactory hydrophilicity to a substrate surface after polished is still unknown. However, it is presumed that an increase of the electrical conductivity i.e., the ionic concentration of the polishing composition ascribed to an organic acid or an organic salt effectively enhances adsorption of hydroxyethyl cellulose to a substrate surface. In contrast, when the ionic concentration of the polishing composition excessively increases, the adsorption of abrasive grains to a substrate surface and adsorption between abrasive grains become excessive. This phenomenon presumably brings excessive physical polishing of a substrate surface by abrasive grains, deteriorating haze level of the substrate surface after polished.

The polishing composition of the present invention has the following advantages.

The polishing composition of the present invention is characterized by containing the composition (A) and at least one selected from an organic acid and an organic salt, wherein the composition (A) contains hydroxyethyl cellulose, abrasive grains, ammonia, and water, and by having an electrical conductivity of 1.2 to 8 times the electrical conductivity of the composition (A). If the electrical conductivity of the polishing composition is 1.2 to 8 times the electrical conductivity of the composition (A), the hydrophilicity of the substrate surface after polishing is improved. Accordingly, the polishing composition of the embodiment can be suitably used for polishing the surface of a substrate, particularly for final polishing of a silicon wafer surface requiring high surface accuracy.

The embodiment of the polishing composition of the present invention may be as follows.

The polishing composition of the present invention may further contain known additives such as an antiseptic agent, if necessary.

The polishing composition of the present invention may be manufactured by dissolving or dispersing aforementioned components other than water in water in accordance with a conventional method. The order of components to be dissolved or dispersed in water is not particularly limited. The dissolution or dispersion method is also not particularly limited. For example, a general method such as stirring using a propeller stirrer or dispersion using a homogenizer can be employed.

The polishing composition of the present invention may be a single-component formulation or a multiple-component formulation containing two or more components. In the case of a multiple-component formulation containing two or more components, individual components such as hydroxyethyl cellulose, abrasive grains, ammonia, and an organic acid and an organic salt may be independently contained or some of components may be contained as a mixture.

The polishing composition of the present invention may be present in a concentrated state during manufacture and when sold. More specifically, the polishing composition of the present invention may be manufactured and sold in the form of a stock solution of the polishing composition. The concentrated polishing composition, which is manufactured or sold in a smaller volume, is advantageous since the costs for transportation and storage can be saved. The concentration rate of the stock solution of the polishing composition is preferably no less than 5 times, more preferably no less than 10 times, and further preferably no less than 20 times, but is not limited to these. The concentration rate herein refers to the volume ratio of a diluted polishing composition relative to the polishing composition stock solution.

The polishing composition of the present invention may be prepared by diluting the polishing composition stock solution with water. Usually, in the polishing step, water having the same impurity level (amount) as the water contained in the polishing composition of the present invention is used. Thus, the case of making a preparation by diluting the polishing composition stock solution with water is advantageous in handling, since the small-volume polishing composition stock solution is transported and a polishing composition can be prepared immediately before use. Furthermore, since the polishing composition stock solution has high stability, this case is advantageous in view of storage stability.

The weight of composition (A)/the weight of at least one selected from an organic acid and an organic salt in the polishing composition is preferably 99.999/0.001 to 90/10. Furthermore, the weight of hydroxyethyl cellulous/the weight of abrasive grains/the weight of ammonia/the weight of water in the composition (A) is preferably 0.01/1/0.01/98.98 to 0.2/1/0.4/98.4.

[2] The Polishing Method and a Substrate Manufacturing Method of the Present Invention

The polishing method of the present invention is a method for polishing a substrate surface by using the aforementioned polishing composition of the present invention. The polishing composition of the present invention can be used by the same apparatus and under the same conditions as used in a conventional step for polishing a substrate.

As the polishing pad used in the polishing method of the present invention, for example, any type of pad such as a nonwoven cloth type, a suede type, a polishing pad containing abrasive grains therein, a polishing pad containing no abrasive grains may be used.

In the polishing method according to the present invention, the temperature during polishing is not particularly limited and preferably 5 to 60° C.

The polishing method of the present invention can be used in any stage of a multiple stage polishing. In the case of manufacturing a semiconductor substrate, particularly a silicon wafer, the polishing method of the present invention can be used for either one of polishing for improving a damage layer of a silicon wafer and polishing for completing the surface layer of a silicon wafer such as final polishing. Particularly, the polishing method of the present invention is preferably used in polishing for completing the surface layer of a substrate, such as final polishing, required to have highly smooth and clear substrate surface after polishing. The time required for polishing for completing the surface layer of a substrate is usually 30 seconds to 30 minutes.

Next, Examples and Comparative Examples of the present invention will be described.

The polishing compositions of Examples 1 to 18 and Comparative Examples 1 to 18 were prepared by adding a whole or part of hydroxyethyl cellulose, abrasive grains, ammonia and at least one selected from an organic acid and an organic salt to ion exchanged water. The constituents and electrical conductivity increase rate of each of the polishing compositions according to Examples 1 to 18 and Comparative Examples 1 to 18 are shown in Table 1. Although it is not shown in Table 1, the polishing compositions of Examples 1 to 12, Comparative Examples 1 to 7 and Comparative Examples 11 to 18 each contained colloidal silica having an average primary particle diameter of 35 nm as abrasive grains, and the polishing compositions of Examples 13 to 18 and Comparative Examples 8 to 10 each contained colloidal silica having an average primary particle diameter of 25 nm as abrasive grains. Furthermore, the polishing compositions of Examples 5 to 12, Comparative Examples 4 to 7 and Comparative Examples 11 to 18 each contained 0.0025% by mass of a polyoxyethylene polyoxypropylene copolymer as a surfactant; whereas the polishing compositions of Example 13 and Comparative Example 8 each contained 0.0013% by mass of a polyoxyethylene polyoxypropylene copolymer. The polishing compositions of Examples 14 to 18 and Comparative Examples 9 and 10 each contained 0.0030% by mass of a polyoxyethylene polyoxypropylene copolymer.

The average primary particle diameter of the colloidal silica used was calculated from the value of specific surface area measured by FlowSorb II 2300 manufactured by Micromeritics. Furthermore, the electrical conductivities of the polishing composition and the composition (A) at a liquid temperature of 25° C. were measured by a conductivity meter DS-14 manufactured by Horiba, Ltd. The electrical conductivity increase rate was obtained by dividing the electrical conductivity of the polishing composition by the electrical conductivity of the composition (A) containing hydroxyethyl cellulose, abrasive grains and ammonia.

The surface of a silicon wafer was polished by using the polishing composition of each of Examples 1 to 18 and Comparative Examples 1 to 18 in the conditions described in Table 2. After polishing, the surface of the silicon wafer was rinsed with running water at a flow rate of 7 L/min. for 10 seconds and stood vertically for 30 seconds. Thereafter, the distances to water droplets repelled from the edge portion of the silicon wafer (water-repellent distance) were measured. The silicon wafer to be used for the measurement of the water-repellent distance was prepared by polishing a silicon wafer having a diameter of 200 mm, a conductive type of P, a crystal orientation of <100> and a resistivity of 0.1 Ω·cm or more and less than 100 Ω·cm, by polishing slurry (trade name GLANZOX 2100) manufactured by Fujimi Incorporated and cutting the silicon wafer into chips 60 mm square.

The greater the value of the above described water-repellent distance, the poorer the hydrophilicity of a silicon wafer surface becomes. In the column of “hydrophilicity” of Table 1, evaluation on hydrophilicity of the silicon wafer surface imparted by each of the polishing compositions of Examples 1 to 18 and Comparative Examples 1 to 18 is shown. “Excellent”, “good” and “poor” mean that, compared to the water-repellent distance in the case where polishing was performed by use of composition (A) containing hydroxyethyl cellulose, abrasive grains and ammonia, the water-repellent distance in the case where polishing was performed by use of a polishing composition containing the aforementioned composition (A) and at least one selected from an organic acid and an organic salt was reduced respectively by 10 mm or more, 5 mm or more, and less than 5 mm.

The haze ascribed to the polishing composition of the present invention was evaluated based on a haze value of a silicon wafer polished in the conditions described in Table 3, which was measured by a wafer detection apparatus (DNO mode), Surfscan SP2, manufactured by KLA-Tencor Corporation. The silicon wafer, which had a diameter of 200 mm, a conductive type of P, a crystal orientation of <100> and a resistivity of 0.1 Ω·cm or more and less than 100 Ω·cm, was used after it was polished by polishing slurry (trade name GLANZOX 2100) manufactured by Fujimi Incorporated. Evaluation on haze of a silicon wafer surface after polishing is shown in the column of “DNO haze” of Table 1. In the table, “excellent”, “good” and “poor” mean that, relative to the haze in the case where polishing was performed by use of composition (A) containing hydroxyethyl cellulose, abrasive grains and ammonia, an increase rate of the haze in the case where polishing was performed by use of a polishing composition containing the aforementioned composition (A) and at least one selected from an organic acid and an organic salt is less than 5%, 5% or more and less than 10% and 10% or more, respectively.

TABLE 1

| | | Water soluble | | | | | | | |
|---|---|---|---|---|---|---|---|---|---|
| | | polymer | | | | | | | |
| | Abrasive | | Weight | | | | | | |
| | grains | | average | | Ammonia | Organic acid | Increase rate | | |
| | Content | | molecular | Content | Content | and organic salt | of electrical | | |
| | [% by mass] | Type | weight | [% by mass] | [% by mass] | Type | conductivity | Hydrophilicity | DNO haze |
| Ex. 1 | 0.15 | HEC | 500,000 | 0.008 | 0.048 | Ammonium tartrate | 1.43 | excellent | excellent |
| Ex. 2 | 0.15 | HEC | 500,000 | 0.008 | 0.048 | Ammonium tartrate | 1.72 | excellent | excellent |
| Ex. 3 | 0.15 | HEC | 500,000 | 0.008 | 0.048 | Ammonium tartrate | 2.01 | excellent | excellent |
| Ex. 4 | 0.15 | HEC | 500,000 | 0.008 | 0.048 | Ammonium tartrate | 7.48 | excellent | good |
| Ex. 5 | 0.46 | HEC | 250,000 | 0.018 | 0.010 | Diammonium hydrogen citrate | 1.37 | good | excellent |
| Ex. 6 | 0.46 | HEC | 250,000 | 0.018 | 0.010 | Diammonium hydrogen citrate | 4.27 | excellent | excellent |
| Ex. 7 | 0.46 | HEC | 250,000 | 0.018 | 0.010 | Diammonium hydrogen citrate | 7.41 | excellent | good |
| Ex. 8 | 0.46 | HEC | 250,000 | 0.018 | 0.010 | Sodium 1-propanesulfonate | 2.38 | excellent | excellent |
| Ex. 9 | 0.46 | HEC | 250,000 | 0.018 | 0.020 | Ammonium acetate | 1.26 | good | excellent |
| Ex. 10 | 0.46 | HEC | 250,000 | 0.018 | 0.020 | Ammonium acetate | 1.62 | excellent | excellent |
| Ex. 11 | 0.46 | HEC | 250,000 | 0.018 | 0.020 | Ammonium acetate | 2.41 | excellent | excellent |
| Ex. 12 | 0.46 | HEC | 250,000 | 0.018 | 0.020 | Ammonium acetate | 3.86 | excellent | excellent |
| Ex. 13 | 0.18 | HEC | 250,000 | 0.009 | 0.005 | Ammonium acetate | 1.98 | excellent | excellent |
| Ex. 14 | 0.31 | HEC | 300,000 | 0.031 | 0.008 | Ammonium acetate | 2.62 | excellent | excellent |
| Ex. 15 | 0.31 | HEC | 300,000 | 0.031 | 0.008 | Ammonium acetate | 3.12 | excellent | excellent |
| Ex. 16 | 0.31 | HEC | 300,000 | 0.031 | 0.008 | Ammonium acetate | 3.98 | excellent | good |
| Ex. 17 | 0.31 | HEC | 300,000 | 0.031 | 0.008 | Triammonium citrate | 1.34 | good | excellent |
| Ex. 18 | 0.31 | HEC | 300,000 | 0.031 | 0.008 | Triammonium citrate | 2.01 | excellent | excellent |
| Com. Ex. 1 | 0.15 | HEC | 500,000 | 0.008 | 0.048 | — | 1.00 | poor | excellent |
| Com. Ex. 2 | 0.15 | HEC | 500,000 | 0.008 | 0.048 | Ammonium tartrate | 1.17 | poor | excellent |
| Com. Ex. 3 | 0.15 | HEC | 500,000 | 0.008 | 0.048 | Ammonium tartrate | 13.86 | excellent | poor |
| Com. Ex. 4 | 0.46 | HEC | 250,000 | 0.018 | 0.010 | — | 1.00 | poor | excellent |
| Com. Ex. 5 | 0.46 | HEC | 250,000 | 0.018 | 0.010 | Diammonium hydrogen citrate | 13.45 | excellent | poor |
| Com. Ex. 6 | 0.46 | HEC | 250,000 | 0.018 | 0.020 | — | 1.00 | poor | excellent |
| Com. Ex. 7 | 0.46 | HEC | 250,000 | 0.018 | 0.020 | Ammonium acetate | 1.11 | poor | excellent |
| Com. Ex. 8 | 0.18 | HEC | 250,000 | 0.009 | 0.005 | — | 1.00 | poor | excellent |
| Com. Ex. 9 | 0.31 | HEC | 300,000 | 0.031 | 0.008 | — | 1.00 | poor | excellent |
| Com. Ex. 10 | 0.31 | HEC | 300,000 | 0.031 | 0.008 | Ammonium acetate | 1.08 | poor | excellent |
| Com. Ex. 11 | 0.46 | — | — | — | 0.010 | — | 1.00 | poor | excellent |
| Com. Ex. 12 | 0.46 | — | — | — | 0.010 | Ammonium acetate | 3.03 | poor | excellent |
| Com. Ex. 13 | 0.46 | PA | 150,000 | 0.018 | 0.010 | — | 1.00 | poor | excellent |
| Com. Ex. 14 | 0.46 | PA | 150,000 | 0.018 | 0.010 | Ammonium tartrate | 2.74 | poor | excellent |
| Com. Ex. 15 | 0.46 | PVA | 115,000 | 0.018 | 0.010 | — | 1.00 | poor | excellent |
| Com. Ex. 16 | 0.46 | PVA | 115,000 | 0.018 | 0.010 | Ammonium tartrate | 3.37 | poor | excellent |
| Com. Ex. 17 | 0.46 | CMC | 50,000 | 0.018 | 0.010 | — | 1.00 | poor | excellent |
| Com. Ex. 18 | 0.46 | CMC | 50,000 | 0.018 | 0.010 | Ammonium tartrate | 2.78 | poor | excellent |

HEC: Hydroxyethyl cellulose
PA: Polyacrylic acid
PVA: Polyvinyl alcohol
CMC: Carboxymethylcellulose

TABLE 2

| | |
|---|---|
| Polishing machine: | Bench-type polishing machine EJ- |
| | 380IN (made by Engis Japan |
| | Corporation) |
| Load for polishing: | 15 kPa |
| Table rotation speed: | 30 rpm |
| Head rotation speed: | 30 rpm |
| Time for polishing: | 1 minute |
| Temperature of polishing | 20° C. |
| composition: | |
| Supply rate of polishing | 0.25 L/min (pouring onto the wafer) |
| composition: | |

TABLE 3

| | |
|---|---|
| Polishing machine: | Single wafer polishing machine PNX- |
| | 322 (made by Okamoto Machine Tool |
| | Works, Ltd.) |
| Load for polishing: | 15 kPa |
| Table rotation speed: | 30 rpm |
| Head rotation speed: | 30 rpm |
| Time for polishing: | 4 minutes |
| Temperature of polishing | 20° C. |
| composition: | |
| Supply rate of polishing | 0.5 L/min (pouring onto the wafer) |
| composition: | |

As shown in Table 1, it was found that the polishing compositions of Examples 1 to 18 improved hydrophilicity without deteriorating the haze level of a silicon wafer surface after polishing compared to those of Comparative Examples 1 to 18.

1. A polishing composition comprising a composition (A) and at least one selected from an organic acid and an organic salt, wherein
the composition (A) contains hydroxyethyl cellulose, ammonia, abrasive grains, and water, and
the electrical conductivity of the polishing composition is 1.2 to 8 times the electrical conductivity of the composition (A).

2. The polishing composition according to claim 1, further comprising a surfactant.

3. A method for polishing a substrate surface by using the polishing composition according to claim 1.

4. A method for manufacturing a substrate, comprising a step for polishing a substrate surface by using the method according to claim 3.

5. A method for polishing a substrate surface by using the polishing composition according to claim 2.

6. A method for manufacturing a substrate, comprising a step for polishing a substrate surface by using the method according to claim 5.
